(19) United States
(12) Patent Application Publication
(10) Pub. No.: US 2013/0146977 A1
(43) Pub. Date: Jun. 13, 2013

(54) SEMICONDUCTOR STRUCTURE AND METHOD FOR MANUFACTURING THE SAME

(71) Applicants: Haizhou Yin, Poughkeepsie, NY (US); Huilong Zhu, Poughkeepsie, NY (US); Zhijiong Luo, Poughkeepsie, NY (US)

(72) Inventors: Haizhou Yin, Poughkeepsie, NY (US); Huilong Zhu, Poughkeepsie, NY (US); Zhijiong Luo, Poughkeepsie, NY (US)

(21) Appl. No.: 13/816,227

(22) PCT Filed: Dec. 1, 2011
(86) PCT No.: PCT/CN11/83323

§ 371 Date: Feb. 9, 2013

(30) Foreign Application Priority Data
Aug. 30, 2011 (CN) 201110252276.5

(51) Int. Cl. H01L 27/12; H01L 21/8238

(52) U.S. Cl. CPC H01L 27/1203; H01L 21/8238
USPC 257/351; 438/154

(57) ABSTRACT

The present invention discloses a semiconductor structure comprising: a semiconductor base located on an insulating layer, which is located on a semiconductor substrate; source/drain regions adjacent to opposite first sides of the semiconductor base; gates, positioned on a second set of two sides of the semiconductor base and said second set of two sides are opposite to each other; an insulating plug located on the insulating layer and embedded into the semiconductor base; and an epitaxial layer located between the insulating plug and the semiconductor base wherein the epitaxial layer is SiC for an NMOS device and the epitaxial layer is SiGe for a PMOS device. The present invention further discloses a method for manufacturing a semiconductor structure. The stress at the channel region is adjusted by forming a strained epitaxial layer, thus carrier mobility is improved and the performance of the semiconductor device is improved.

The present application claims priority benefit of Chinese Patent application “Semiconductor Structure and Method for Manufacturing the Same”, Ser. No. 201110252276.5, filed on Aug. 30, 2011, the subject matter of which is incorporated herein by reference in its entirety.

### FIELD OF THE INVENTION

The present invention relates to the field of semiconductor technologies, particularity, to a semiconductor structure and a method for manufacturing the same.

### BACKGROUND OF THE INVENTION

As the channel length of Metal-Oxide-Semiconductor Field-Effect Transistors (MOSFET) continually decreases, some effects that used to be ignored in the MOSFET long channel models now become increasingly prominent, and even become the major factors that unfavorably impact the device performance. Such phenomena are generally referred to as the short-channel effects. The short-channel effects deteriorate the electrical properties of the devices. For example, they may cause decrease in gate threshold voltage, increase in power consumption and reduction of Signal-to-Noise Ratio (SNR).

Currently, the leading technique in the art for minimizing the adverse effect of short-channels is to improve the technologies for traditional planar devices, specifically reducing the thickness of the channel region and removing the neutral layer at bottom of the depletion layer in the channel, so as for the depletion layer in the channel to fill the channel region completely—this is the so-called Fully Depleted (FD) device, which is significantly different from the traditional Partially Depleted (PD) planar device.

In order to make a Fully Depleted (FD) device, however, the silicon layer at the channel region must be very thin. It is generally difficult to manufacture a desired structure with the required thickness by the traditional manufacturing process especially when the process is based on bulk silicon, or the manufacturing costs for such devices are costly. Even using the new SOI (Silicon-on-Insulator) process, it is still challenging to keep the thickness of the silicon layer in the channel at a required thinness level. Therefore, alternative methods to make a FD device have been explored. In order to realize a FD device, more of the current research and development effort have shifted to make three-dimensional device structures using FD dual-gate or tri-gate technologies.

The three-dimensional device structure (also referred to as the vertical device in the art) is referred to a device having a structure that the cross-section of source/drain regions and the cross-section of the gate are not co-located on the same plane, which is essentially a FinFET (Fin Field-Effect Transistor) structure.

The three-dimensional device structure allows the channel region to be separated from the bulk silicon or SOI, rather than being embedded therein, which makes it possible to manufacture a very thin FD channel by etching or other similar techniques.

The three-dimensional semiconductor device which has been disclosed in the prior art is shown in FIG. 1, and comprises a three dimensional semiconductor base 020 located on top of an insulating layer 010; source and drain regions 030 in connection with first opposite sides 022 of the semiconductor base 022; and gates 040 located on second sides 024 adjacent to the first sides 022 in the semiconductor base 020 (A gate dielectric layer and a work function metal layer located between the gate 040 and the semiconductor base 020 are not shown in the figure for clarification purposes). In the aforementioned structure, in order to reduce the resistance at the source and drain regions, the boundaries of the source and drain regions 030 can be further extended, so that the width of the source and drain regions 030 (in the direction of XX′) can be greater than the thickness of the semiconductor base 020. The three-dimensional semiconductor structure is expected to be employed in the technology node of 22 nm or beyond. However, the short-channel effects may become major factors affecting performance of the three dimensional devices because of the further reduced size.

It is known that speed of MOS transistors may be effectively increased by the strained silicon technology, which may improve the electron mobility of NMOS transistors and the hole mobility of PMOS transistors, and reduce the serial resistance at source and drain of MOS transistors, so as to compensate the more pronounced Coulomb scattering effect due to high dopant concentration in the channel, and compensate the mobility degradation arising from the increase of effective electrical field intensity and the enhancement of interface scattering caused by reducing the thickness of the gate dielectric. Currently, the strained silicon has been widely applied in the technology nodes of 90 nm and beyond, and has become an important technical approach to drive Moore's Law further.

### SUMMARY OF THE INVENTION

In order to solve the aforesaid problems, the present invention discloses a semiconductor structure and a method for manufacturing the same, where the strained silicon is introduced into three-dimensional semiconductor devices, thereby increasing the carrier mobility and enhancing performance of the device.

The present invention discloses a semiconductor structure comprising: a semiconductor base located on an insulating layer, which is located on a semiconductor substrate; source and drain regions in contact with a first set of two sides of the semiconductor base and the first set of the two sides are opposite to each other; gates located on a second set of two sides of the semiconductor base and the second set of the two sides are opposite to each other; an insulating plug located on the insulating layer and embedded into the semiconductor base; and an epitaxial layer located between the insulating plug and the semiconductor base, wherein the epitaxial layer is SiC for NMOS devices and the epitaxial layer is SiGe for PMOS devices.

The present invention discloses a method for manufacturing a semiconductor structure, comprising: forming an insulating layer on a semiconductor substrate; forming a semiconductor base on the insulating layer; forming gates located on a first set of two sides of the semiconductor base and the first set of two sides are opposite to each other; forming source and drain regions in contact with a second set of two sides of the semiconductor substrate and the second set of two sides are opposite to each other; removing a part of the material in the semiconductor base to form a cavity within the semiconductor base, wherein the cavity exposes the insulating layer; forming an epitaxial layer by means of selective epitaxy of SiGe or SiC; and forming an insulating plug in the cavity.

As compared to the prior art, the technical solution disclosed by the present invention exhibits following advantages:

The present invention is capable of adjusting stress at the channel region, improving carrier mobility and enhancing performance of the semiconductor device, by forming the cavity in the semiconductor structure followed forming a strained epitaxial layer in the cavity by means of selective epitaxy.

Optionally, the short-channel effects may be further alleviated by forming a cavity in the semiconductor base and embedding an insulating plug into the cavity so as to form an isolation region between the source and drain regions. Moreover, when the stress of the insulating plug is adjusted, for example, the PMOS device has a tensile stress and the NMOS device has a compressive stress, the stress of the insulating plug acts upon the semiconductor base, and an opposite stress can be produced in the semiconductor base, that is, a compressive stress can be produced in the semiconductor base of the PMOS device, and a tensile stress can be produced in the semiconductor base of the NMOS device. The opposite stress generated within the semiconductor base can be used to further regulate the stress in the channel region of the device resulting in improvement in carrier mobility in the channel region.

### BRIEF DESCRIPTION OF THE DRAWINGS

Other characteristics, objectives and advantages of the present invention are made more evident according to the following detailed description of exemplary embodiment(s) in conjunction with accompanying drawings, wherein the same or similar reference signs in the drawings denote the same or similar elements.

The following cross-sectional views are resulted from the structures taken along the line AA′ or BB′ given in respective top views.

FIG. 1 diagrammatically illustrates an exemplary semiconductor structure in the prior art;

FIG. 2 diagrammatically illustrates an exemplary three-dimensional semiconductor structure according to the aspects of the present invention;

FIG. 3 and FIG. 4 diagrammatically illustrate a top view and a cross-sectional view along line AA′ after the material layers for an exemplary semiconductor structure are formed on a substrate according to an embodiment of the method for manufacturing a semiconductor structure in accordance with the present invention;

FIG. 5 and FIG. 6 diagrammatically illustrate a top view and a cross-sectional view along line AA′ after a protective layer and a sacrificial layer are patterned in an embodiment of the method for manufacturing the semiconductor structure in accordance with the present invention;

FIG. 7 and FIG. 8 illustrate a top view and a cross-sectional view along line AA′ after first sidewall spacers are formed in an embodiment of the method for manufacturing the semiconductor structure in accordance with the present invention;

FIG. 9 and FIG. 10 illustrate a top view and a cross-sectional view along line AA′ after a stop layer and a silicon layer are patterned in an embodiment of the method for manufacturing the semiconductor structure in accordance with the present invention;

FIG. 11 and FIG. 12 respectively illustrate a cross-sectional view along line AA′ and a top view after gates are formed in an embodiment of the method for manufacturing the semiconductor structure in accordance with the present invention;

FIG. 13 and FIG. 14 illustrate a top view and a cross-sectional view along line BB′ after the stop layers of source and drain regions are exposed in an embodiment of the method for manufacturing the semiconductor structure in accordance with the present invention;

FIG. 15 and FIG. 16 respectively illustrate a top view and a cross-sectional view along line BB′ after second sidewall spacers are formed in an embodiment of the method for manufacturing the semiconductor structure in accordance with the present invention;

FIG. 17 illustrates a structural cross-sectional view of forming source and drain basic layers in the source and drain regions in an embodiment of the method for manufacturing the semiconductor structure in accordance with the present invention;

FIG. 18 illustrates a top view of performing ion implantation after the formation of the source and drain basic layers in an embodiment of the method for manufacturing the semiconductor structure in accordance with the present invention;

FIG. 19 and FIG. 20 respectively illustrate a top view and a cross-sectional view along line BB′ after the formation of a second semiconductor layer on the source and drain basic layers in an embodiment of the method for manufacturing the semiconductor structure in accordance with the present invention;

FIG. 21 and FIG. 22 respectively illustrate a top view and a cross-sectional view along the line BB′ after the formation of a planarized first dielectric layer in an embodiment of the method for manufacturing the semiconductor structure in accordance with the present invention;

FIG. 23 and FIG. 24 respectively illustrate a top view and a cross-sectional view along line AA′ after the formation of a gate in an embodiment of the method for manufacturing the semiconductor structure in accordance with the present invention;

FIG. 25 and FIG. 26 illustrate a top view and a cross-sectional view along the line AA′ after the formation of a planarized second dielectric layer in an embodiment of the method for manufacturing the semiconductor structure in accordance with the present invention;

FIG. 27 and FIG. 28 illustrate a top view and a cross-sectional view along line AA′ after the formation of a cavity in an embodiment of the method for manufacturing the semiconductor structure in accordance with the present invention;

FIG. 29 illustrates a cross-sectional view of the formation of an epitaxial layer in the cavity in an embodiment of the method for manufacturing the semiconductor structure in accordance with the present invention;

FIG. 30 illustrates a cross-sectional view after the formation of an insulating plug in the cavity in an embodiment of the method for manufacturing the semiconductor structure in accordance with the present invention;

FIG. 31 and FIG. 32 illustrate cross-sectional views of the gate and the source/drain regions exposed after the removal of the second dielectric layer in an embodiment of the method for manufacturing the semiconductor structure in accordance with the present invention; and

FIG. 33 and FIG. 34 illustrate cross-sectional views after the formation of contact regions on the gate and the source/drain regions in an embodiment of the method for manufacturing the semiconductor structure in accordance with the present invention.

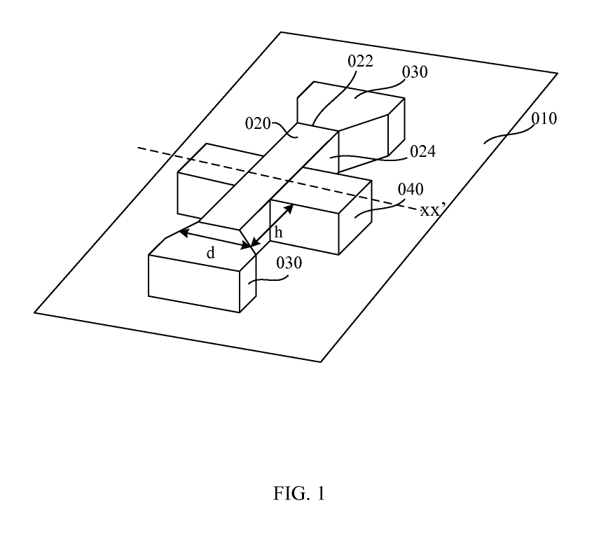

### DETAILED DESCRIPTION OF THE INVENTION

The objectives, technical solutions and advantages of the present invention are made more evident according to the following detailed description of exemplary embodiments in conjunction with the accompanying drawings.

Embodiments of the present invention are described here below, wherein the examples of the embodiments are illustrated in the drawings, in which the same or similar reference signs throughout denote the same or similar elements or elements have same or similar functions. It should be appreciated that the embodiments described below in conjunction with the drawings are illustrative, and are provided for explaining the present invention only, thus shall not be interpreted as a limitation to the present invention.

Various embodiments or examples are provided herein to implement different structures of the present invention. To clarify the disclosure of the present invention, descriptions of the components and arrangements of the specific examples are given below. However, they are only illustrative and shall not be interpreted as limiting the present invention. Moreover, in the present invention, reference numbers and/or letters may be repeated in different examples. Such repetition is for the purpose of simplification and clarification, yet does not denote any relationship between respective embodiments and/or arrangements being discussed. Furthermore, the present invention provides various examples for various processes and materials. However, it is obvious for a person of ordinary skill in the art that other processes and/or materials may alternatively be utilized. In addition, the following structure where a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other. The relationship of the various structures presented herein includes any essential extension made according to the needs of the process or manufacturing. For example, the term “perpendicular” indicates that the difference between the angle at two planes and 90 degrees is in the tolerance of technical or manufacturing error.

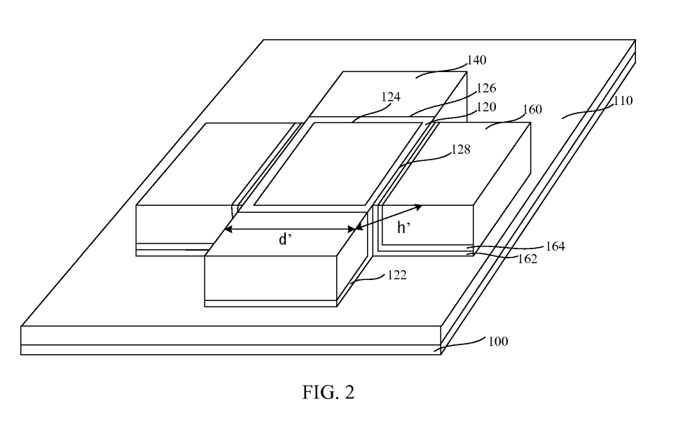

As shown in FIG. 2, the semiconductor structure in accordance with the present invention comprises a semiconductor base 120 located on an insulating layer 110, which is located on a semiconductor substrate 100; source and drain regions 140 adjacent to opposite first sides 126 of the semiconductor base 120; gates 160 located on opposite second sides 128 of the semiconductor base 120; an insulating plug 124 located on the insulating layer 110 and embedded into the semiconductor base 120; and an epitaxial layer 180 (not shown) located above the insulating layer 110 and located between the insulating plug 124 and the semiconductor base 120. For an NMOS device, the epitaxial layer may be SiC. And for a PMOS device, the epitaxial layer may be SiGe. The epitaxial layer 180 is preferably located between the insulating plug 124 at one of the second sides 128 and the semiconductor base 120.

The epitaxial layer 180 can adjust the stress of the channel region, so as to increase carrier mobility and enhance performance of the semiconductor device. Optionally, the insulating plug 124 is made of a stress material. In one example, the insulating plug 124 in a PMOS device has a tensile stress. In another example, the insulating plug 124 in an NMOS device has a compressive stress. By changing the stress of the insulating plug 124, the stress of the insulating plug 124 acts upon the semiconductor base 120 and produces an opposite stress in the semiconductor base 120. In one example, a compressive stress is produced in the semiconductor base 120 of the PMOS device. In another example, a tensile stress is produced in the semiconductor base 120 of the NMOS device. The opposite stress generated in the semiconductor base can be used to further regulate the stress in the channel region and lead to further improvement of the carrier mobility inside the channel region.

In the present invention, the semiconductor base 120 may be silicon formed on the insulating layer 110. A doped region (e.g. a diffusion region and a halo) has already been formed in the semiconductor base 120 in order to provide the channel region for the device. In one embodiment of the present invention, in the semiconductor structure, a channel layer is located between the second sides 128 and the epitaxial layer 180, and a mask layer is located between the second sides 128 and the insulating plug 124. The channel layer is located between the insulating layer 110 and the mask layer in the direction perpendicular to the semiconductor substrate 100. In one example, the material for the channel layer can be silicon (which has already formed in the doped region). The thickness of the channel layer is between 5 nm-40 nm in the direction perpendicular to the second sides. In another example, the material for the mask layer can be Si₃N₄, or stacked SiO₂ and Si₃N₄. In addition, the first sides may be perpendicular to the second sides. The term “perpendicular” means substantially perpendicular in the range of tolerance of the semiconductor manufacturing process.

The material for the semiconductor substrate 100 is silicon. In the direction perpendicular to the semiconductor substrate 100, the insulating plug 124 is positioned at least higher than the channel layer, because such arrangement is favorable for applying stress evenly to the channel region. The material for the insulating plug 124 is one of Si₃N₄, SiO₂ and Si₂N₂O, or any combination of them.

In another embodiment of the present invention, the semiconductor structure further comprise a semiconductor auxiliary base 122, which is adjacent to the first sides 126; the source and drain regions 140 may be formed on the semiconductor auxiliary base 122. In one example, the material for the semiconductor auxiliary base 122 is Si. And the source and drain regions 140 may be formed on the semiconductor auxiliary base 122 by means of ion implantation. Additionally, the upper surface of the semiconductor auxiliary base 122 may be lower than the upper surface of the semiconductor base 120. Herein, the upper surface indicates the surface of the semiconductor auxiliary base 122, the semiconductor base 120 or the semiconductor substrate 100 that is parallel to the insulating layer 110. In this case, the source and drain regions 140 may be formed on the semiconductor auxiliary base 122 by means of epitaxy. As a result, the stress in the channel region is further adjusted by the source and drain regions 140, so as to improve the carrier mobility inside the channel region.

In another embodiment of the present invention, the gates 160 may be formed on the second sides 128 by stacking a gate dielectric layer 162 and a work function metal layer 164. In one example, the material for the gate dielectric layer 162 may be a hafnium-based material, for instance, any one or combinations of HfO2, HfSiO, HfSiON, HfTaO, HfTiO and HfZrO, or may be any one or combinations of Al₂O₃, La₂O₃, ZrO₂, SiO₂ and Si₂N₂O, and its combinations with hafnium-based materials. In another example, the gate dielectric layer may comprise a multi-layer structure, wherein the adjacent layers may be made of different materials. Further, the work function metal layer 164 may include any one or combinations of TiN, TiAlN, TaN and TaAlN. In one example, the gate 160 is a metal gate. In one preferred example, the gate is a poly-silicon gate which is advantageous for better process control. Additionally, a mask layer is located between the second sides 128 and the insulating plug 124. The channel layer is located between the second sides 128 and the epitaxial layer 180, or the channel layer is located between the second sides 128 and the insulating plug 124. In the direction perpendicular to the semiconductor substrate 100, the channel layer is located between the insulating layer 110 and the mask layer. In the direction perpendicular to the semiconductor substrate 100, the gates 160, the insulating plug 124 and the sidewall spacer are at least higher than the channel layer and the epitaxial layer 180.

In still another embodiment of the present invention, a method for manufacturing a semiconductor structure is disclosed.

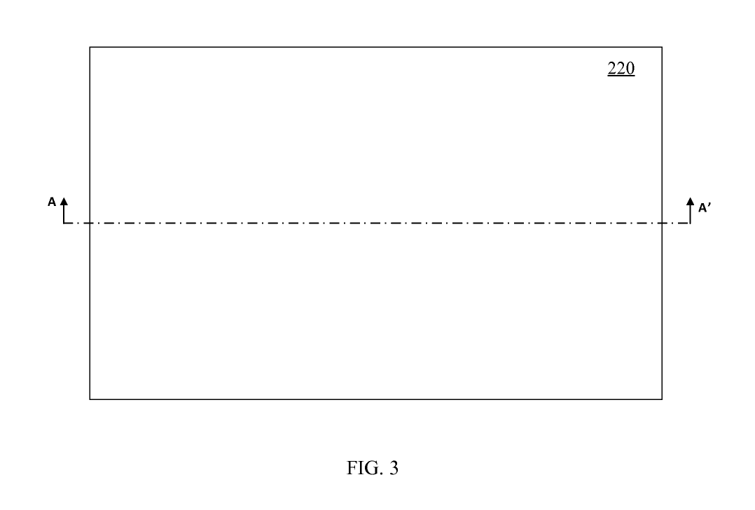

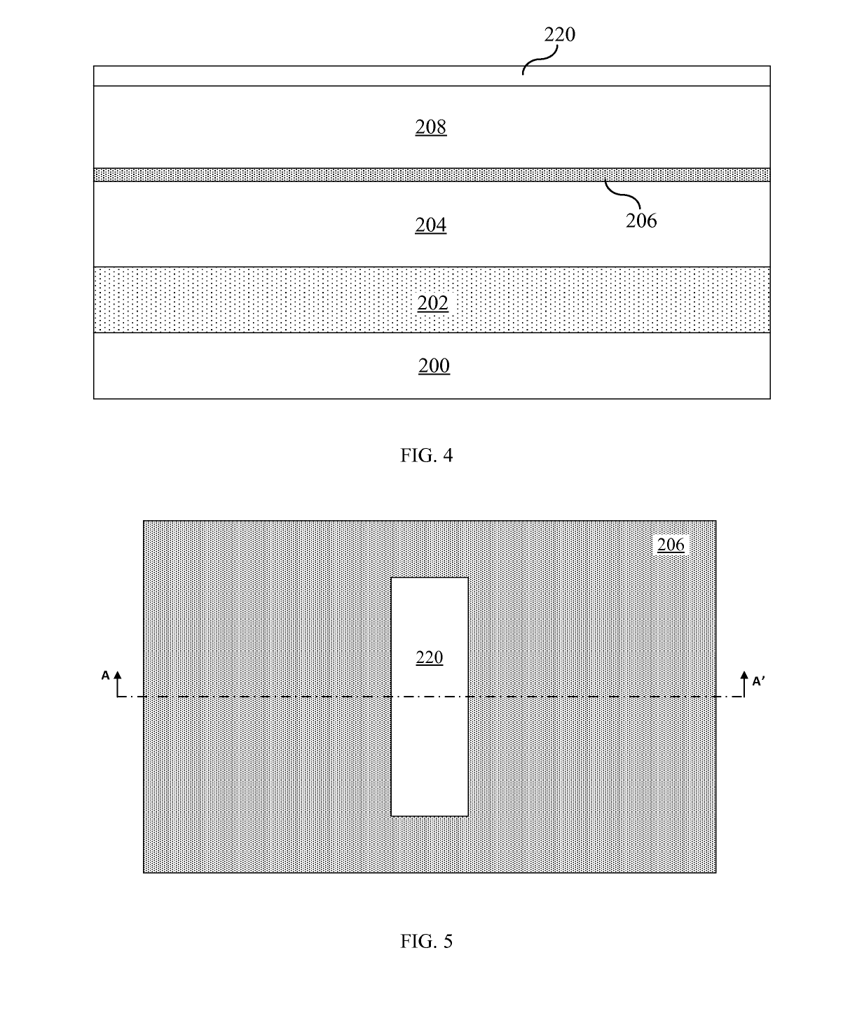

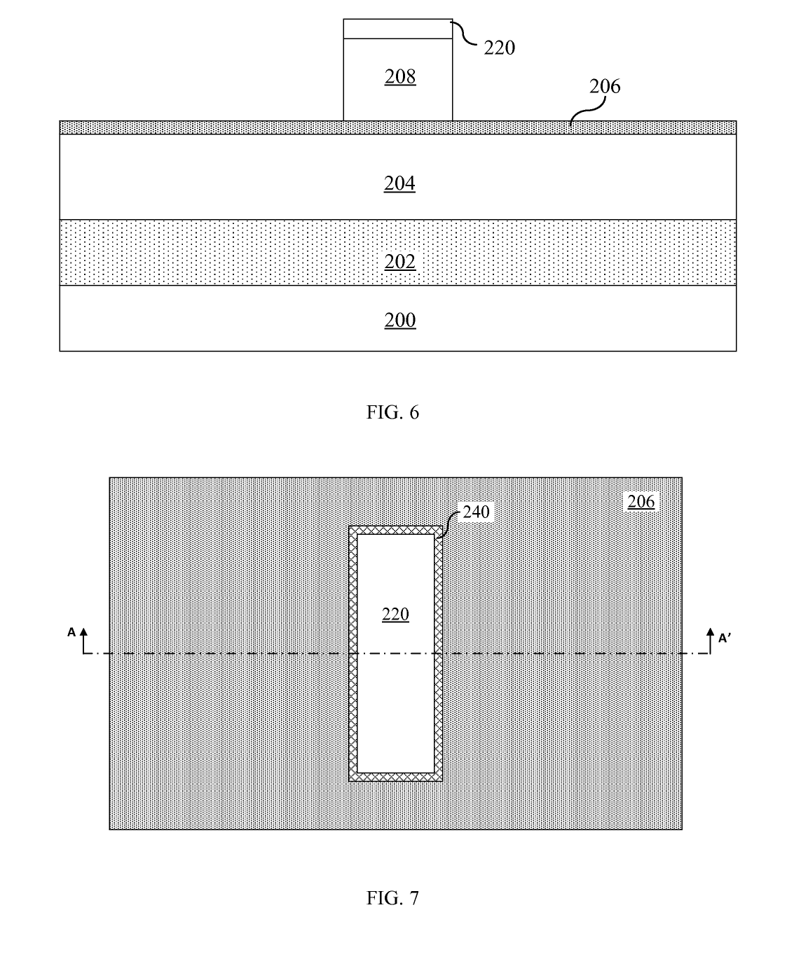

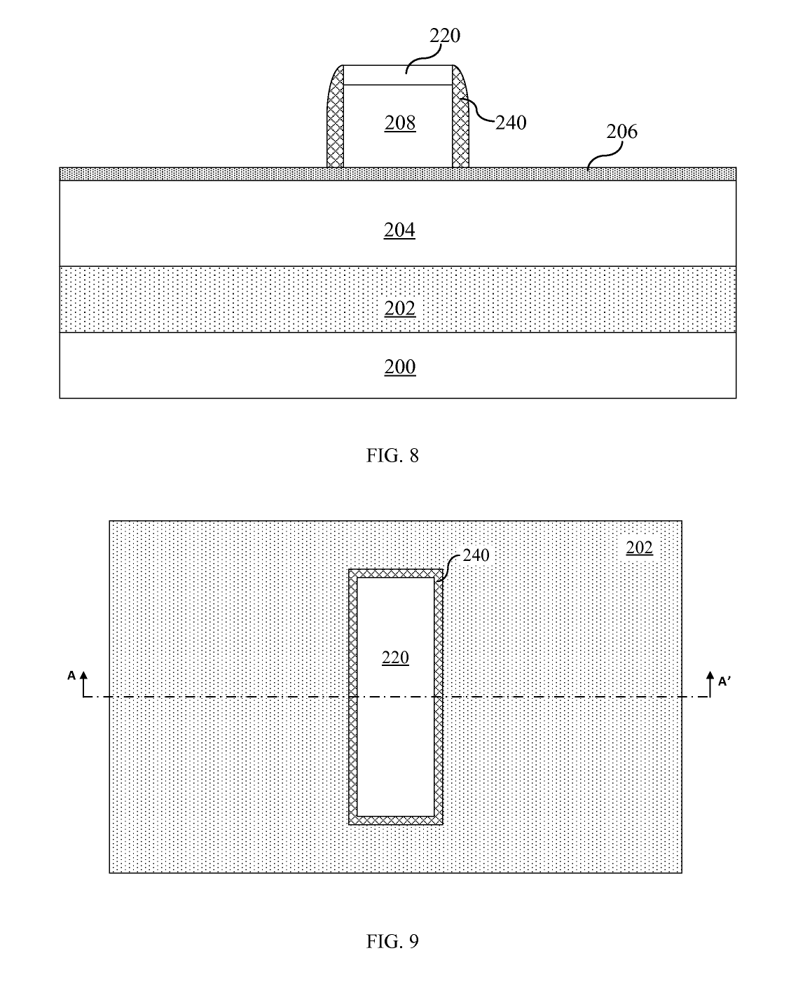

First, as shown in FIG. 3 and FIG. 4, a stop layer 206 (may be SiO₂), a sacrificial layer 208 (may be amorphous Si) and a protective layer 220 (may be SiC) are formed sequentially on Silicon-on-Insulator (SOI) (The Si layer is the first semiconductor layer, which may be made of other semiconductor materials. The SOI is composed of an insulating layer 202 and a Si layer 204 formed sequentially on a substrate 200. The substrate 200 is preferably a Si substrate). As shown in FIG. 5 and FIG. 6, the protective layer 220 and the sacrificial layer 208 are patterned. The patterning may be implemented by means of etching process, which may stop at the stop layer 206. Then, as shown in FIG. 7 and FIG. 8, first sidewall spacers 240 are formed to surround the patterned protective layer 220 and the sacrificial layer 208, and the material for the first sidewall spacer 240 may be Si₃N₄. The first sidewall spacer 240 may be formed by an etching back process. In addition, the first side may be perpendicular to the second side.

Further, in one example, the thickness of the Si layer 204 may be in a range of about 50-100 nm, for example, 60 nm, 70 nm, 80 nm or 90 nm. In another example, the thickness of the stop layer 206 may be in a range of about 5 nm-20 nm, for example, 8 nm, 10 nm, 15 nm or 18 nm. In another example, the thickness of the sacrificial layer 208 may be in a range of about 30 nm-80 nm, for example, 40 nm, 50 nm, 60 nm or 70 nm. In still another example, the thickness of the protective layer 220 may be in a range of about 20-50 nm, for example, 25 nm, 30 nm, 35 nm or 40 nm. In yet another example, in the direction perpendicular to the second sides, the thickness of the first sidewall spacer 240 may be in a range of about 5 nm-40 nm, for example, 10 nm, 20 nm, 25 nm or 30 nm.

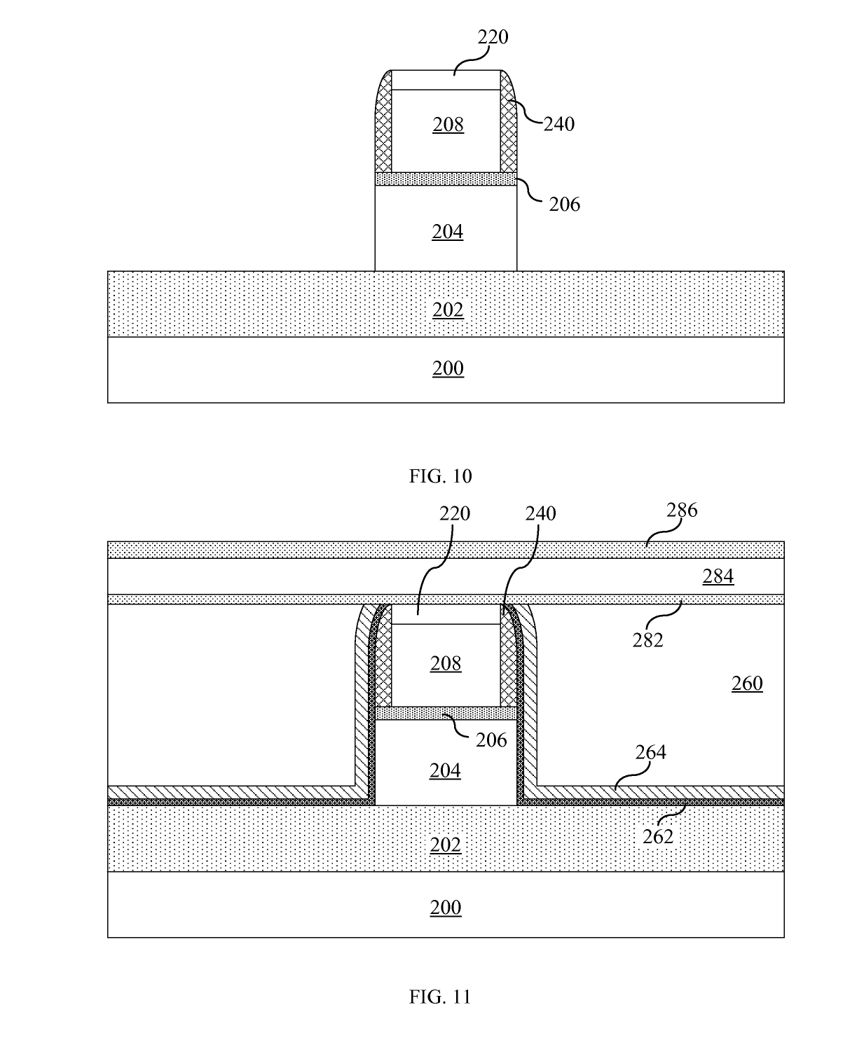

As shown in FIG. 9 and FIG. 10, the stop layer 206 and the Si layer 204 are patterned with the first sidewall spacers 240 functioning as masks. The patterning operation may be implemented by means of etching, and the etching process stops at the insulating layer 202.

Then, a gate of the semiconductor structure is formed. The gate (The gate is in fact a gate stack layer comprising the gate. The gate stack layer comprises a gate dielectric layer, a work function metal layer and a poly-Si layer stacked one by one. The poly-Si layer may be replaced by stacked metal layers) may be formed after the stop layer and the Si layer have been patterned, and before the stop layers at the source and drain regions are exposed.

Specifically, as shown in FIG. 11, after the stop layer 206 and the Si layer 204 are patterned (in FIG. 9 and FIG. 10), the gate stack layer is formed on the insulating layer 202 (wherein the gate stack layer comprises the gate dielectric layer 262, the work function metal layer 264 and a gate material layer 260 that are stacked sequentially, wherein the gate dielectric layer 262 may be made of a hafnium-based material selecting from, for example, any one or combinations of HfO₂, HfSiO, HfSiON, HfTaO, HfTiO and HfZrO, or any one or combinations of Al₂O₃, La₂O₃, ZrO₂, SiO₂ and Si₂N₂O, and its combinations with a hafnium-based material. The material for the work function metal layer 264 may include any one or combinations of TiN, TiAlN, TaN and TaAl. The gate material layer 260 may be metals, and preferably poly-silicon). Then the gate stack layer is planarized to expose the protective layer 220. Next, an auxiliary mask layer is formed to cover the gate stack layer and the protective layer 220. The auxiliary mask layer may be a stacked dielectric layer formed of different materials. In one example, the material for the protective layer 220 and the first sidewall spacers 240 is Si₃N₄, the auxiliary mask layer may be a stack of a SiO₂ layer (the first auxiliary mask layer 282)-a Si₃N₄ layer (the second auxiliary mask layer 284)-a SiO₂ layer (the third auxiliary mask layer 286). After aforesaid operations have been implemented, only the SiO₂ layer can be seen in the top view of the substrate that carries the aforesaid structure.

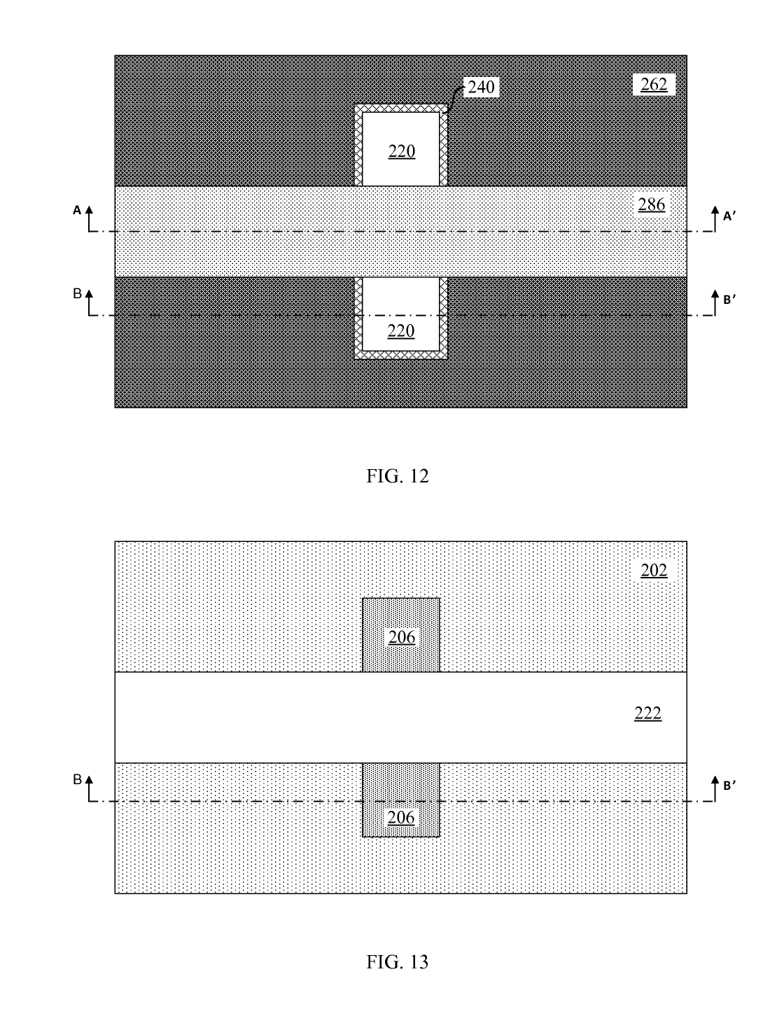

Next, as shown in FIG. 12, the gate is patterned. The auxiliary mask layer (which may comprise multiple layers), the gate material layer 260 and the work function metal layer 264 are etched. The etching may stop at the gate dielectric layer 262 and the protective layer 220, so as to expose the first sidewall spacers 240.

The thickness of the gate dielectric layer 262 may be 1 nm-5 nm, for example, 2 nm and 4 nm. In addition, an interface oxide layer may be further formed before the formation of the gate dielectric layer 262, and in one example, the thickness of the interface oxide layer may be between 0.2 nm-0.7 nm, for example, 0.5 nm (both are not shown). In another example, the thickness of the work function metal layer 264 is between 3 nm-10 nm, for example, 5 nm or 8 nm. In another example, the thickness of the gate material layer 260 may be 50 nm-100 nm, for example, 60 nm, 70 nm, 80 nm or 90 nm. In still another example, the thickness of the first auxiliary mask layer 282 may be 2 nm-5 nm, for example 3 nm or 4 nm. In yet another example, the thickness of the second auxiliary mask layer 284 may be 10 nm-20 nm, for example, 12 nm, 15 nm or 18 nm. And the thickness of the third auxiliary mask layer 286 may be 10 nm-20 nm, for example, 12 nm, 15 nm or 18 nm.

The aforesaid method for forming the gate is provided in consideration of integration of the manufacturing processes, and the subsequent description is thus given based on such a method. However, it should be noted that the gate may be formed by other methods, and the gate may also be formed after the formation of the source and drain regions. According to the teaching of the present invention, a person of ordinary skills in the art is able to form the gate in a very flexible manner, and thus no detailed description is given here in order not to obscure the aspects of the present invention.

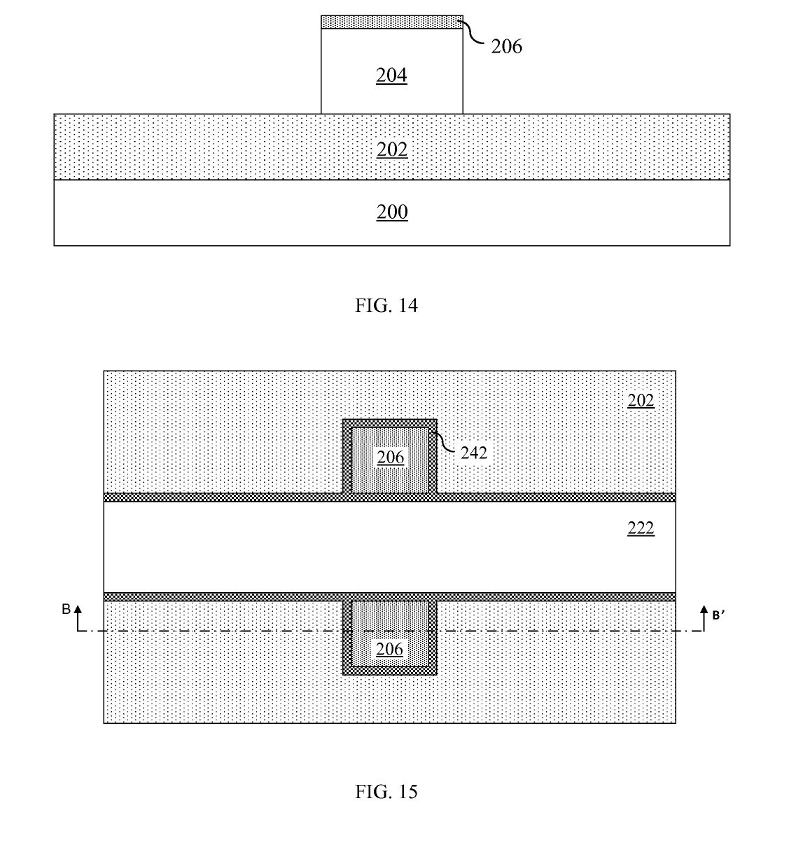

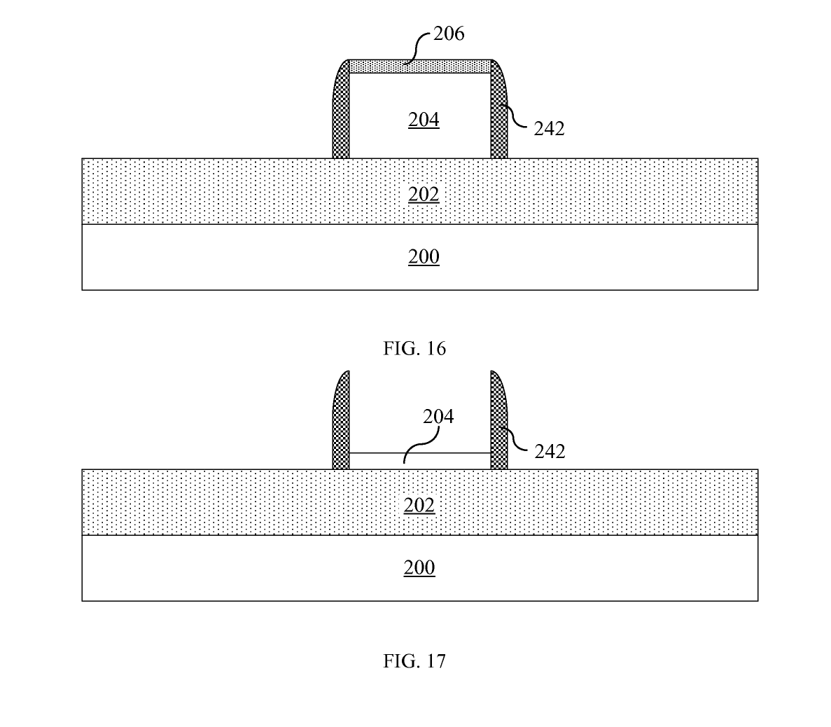

Then, as shown in FIG. 13 and FIG. 14, the source and drain regions are determined, and the first sidewall spacers 240, the protective layer 220 and the sacrificial layer 208 that cover the source and drain regions are removed to expose the stop layers 206 (Hard masks 222 may be formed on other regions than the source and drain regions. The hard mask 222 may be provided on the protective layer 220 at any of aforesaid steps and it may be removed at a step as appropriate. In one example, the hard mask is removed after the stop layers 220 in the source and drain regions are exposed). Meanwhile, the sides of the protective layer 220 and the sacrificial layer 208 that are adjacent to the source and drain regions are also exposed (not shown). Then, as shown in FIG. 15 and FIG. 16, second sidewall spacers 242 (may be Si₃N₄) are formed to surround the protective layer 220, the sacrificial layer 208, the patterned stop layer 206 and Si layer 204. Subsequently, the semiconductor substrate is formed (in one embodiment of the method, the first sides indicate the side surfaces exposed from the removal of the source and drain regions). The thickness of the second sidewall spacers 242 may be 7 nm-20 nm, for example, 10 nm, 15 nm or 18 nm.

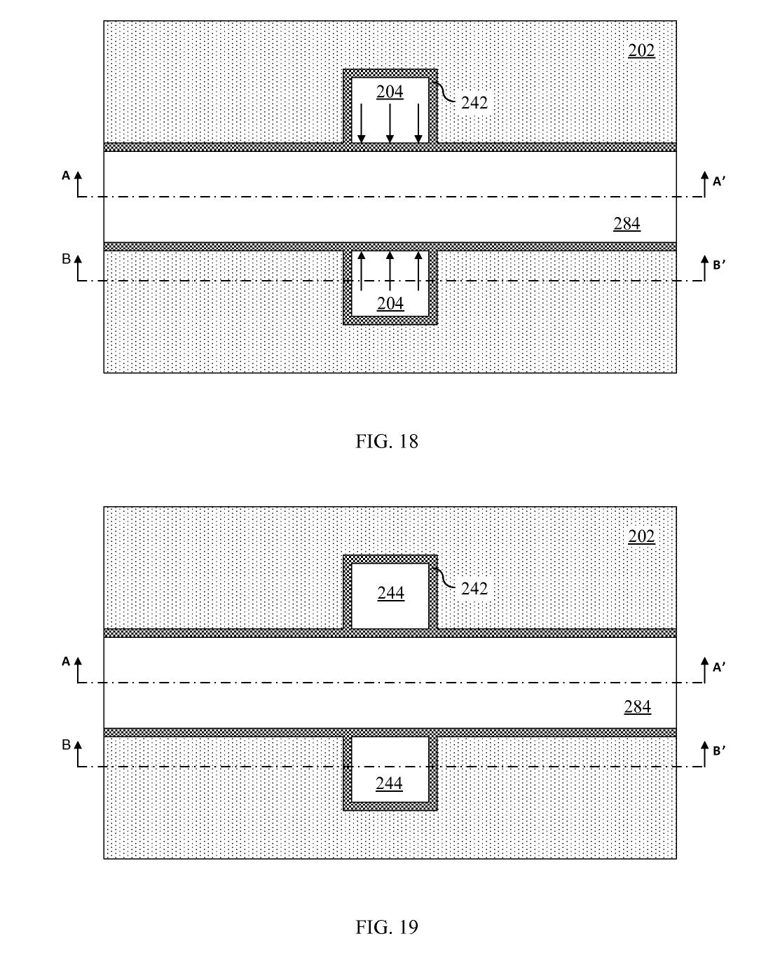

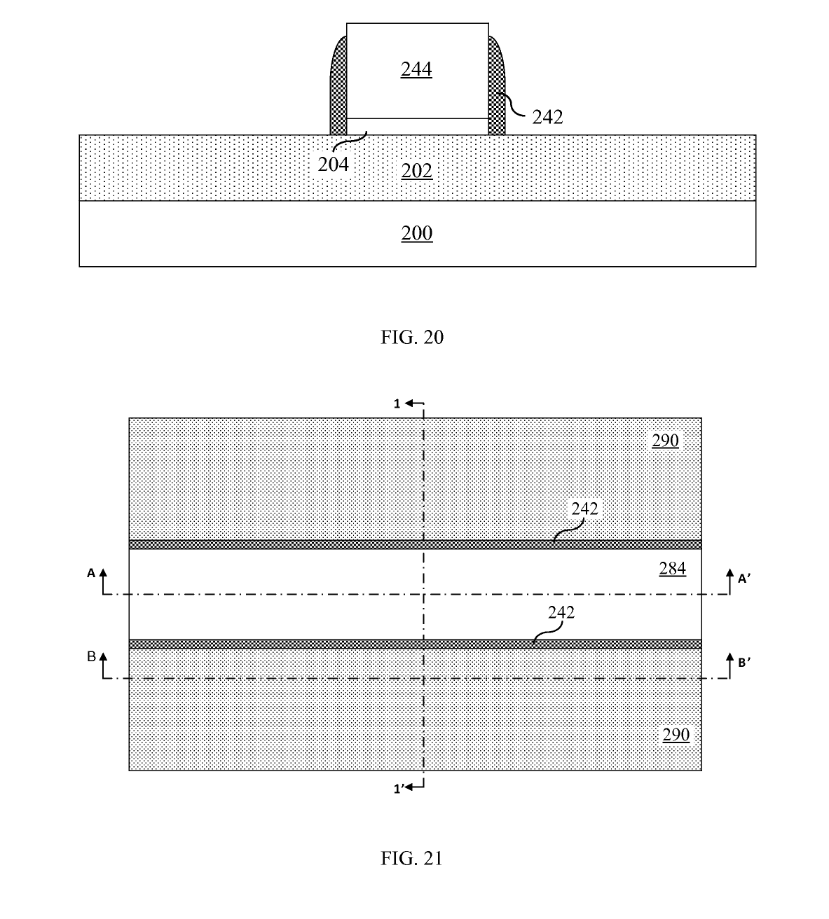

Referring to FIG. 17, after the semiconductor substrate has been formed, the stop layer 206 and a portion with a certain thickness of the Si layer 204 located in the source and drain regions are removed (in this case, the first auxiliary mask 286 located on the gate stack layer, i.e. the SiO₂ layer, is also removed), so as to form source and drain basic layers (i.e. the semiconductor auxiliary bases), whose thickness may be 5 nm-20 nm, for example, 10 nm or 15 nm. Further referring to FIG. 18, ion implantation is performed along the directions (as denoted by the arrow in the Figure) facing the first sides (which indicate the surface of the Si layer exposed from removal of the portion with a certain thickness of the Si layer), such that a diffusion region and a halo region are formed in the Si layer 204. As compared to the ion implantation performed along the directions facing the second sides in the prior art, the present invention is more favorable in practice, and is also advantageous for reducing the distance between neighboring semiconductor bases, reducing the utilization area of the device and reducing the manufacturing cost as well. All the specific processes of the ion implantation, such as implantation energy, implantation dose, dopants and the number of implantations, may be adjusted flexibly according to the product designs, and thus are not described here in detail. Then, as shown in FIG. 19 and FIG. 20, the source and drain regions may be formed, after second semiconductor layers 244 are formed on the source and drain basic layers by means of an epitaxy method (for PMOS devices, the material for the second semiconductor layer 244 is Si_{1-X}Ge_{X}, and the doping dose may be 1×10¹⁹/cm³−1×10²¹/cm³; for an NMOS device, the material for the second semiconductor layer 244 may be Si: C, and the doping dose may be 1×10¹⁹/cm³−1×10²¹/cm³). The source and drain regions are used to further adjust the stress in the channel region, thereby improving the carrier mobility in the channel region. Additionally, the source and drain regions may also be formed by way of performing ion implantation to the Si layer 204 instead of removing a portion with certain thickness of the Si layer 204, after removal of the stop layers 206 located at the source and drain regions.

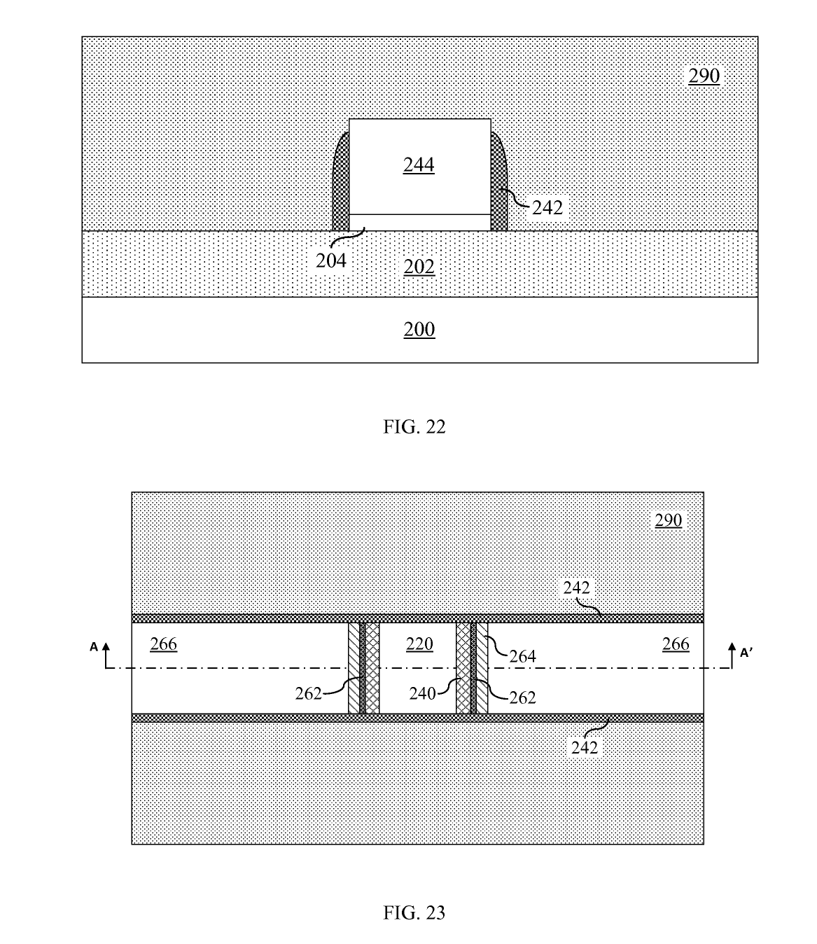

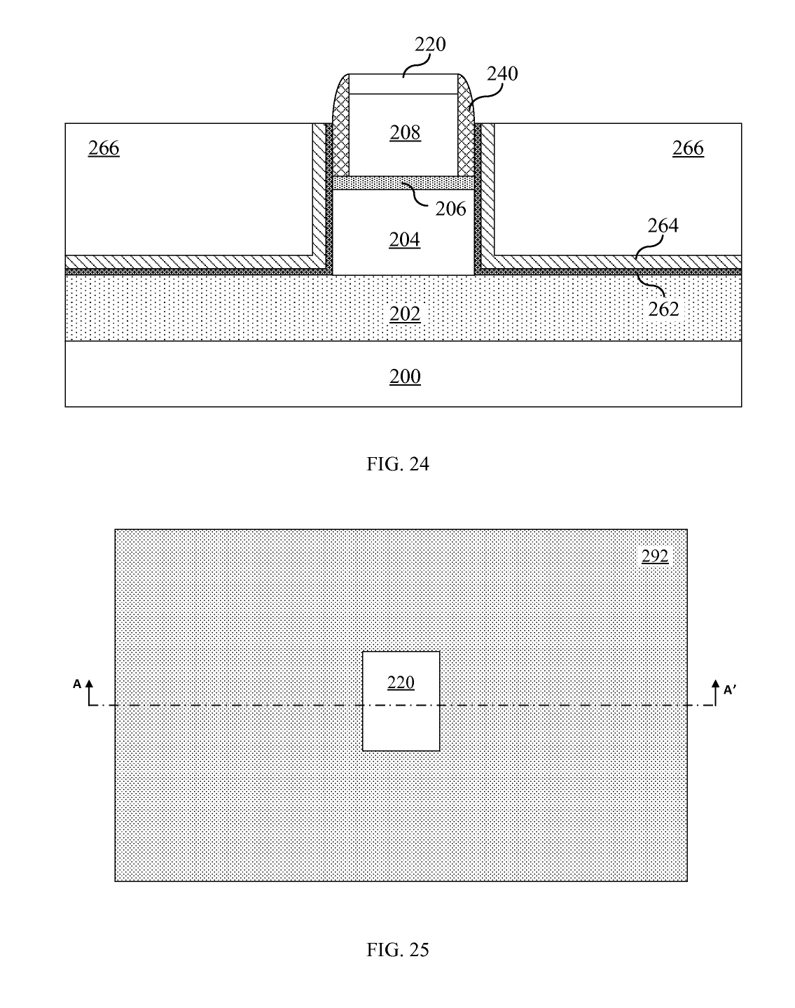

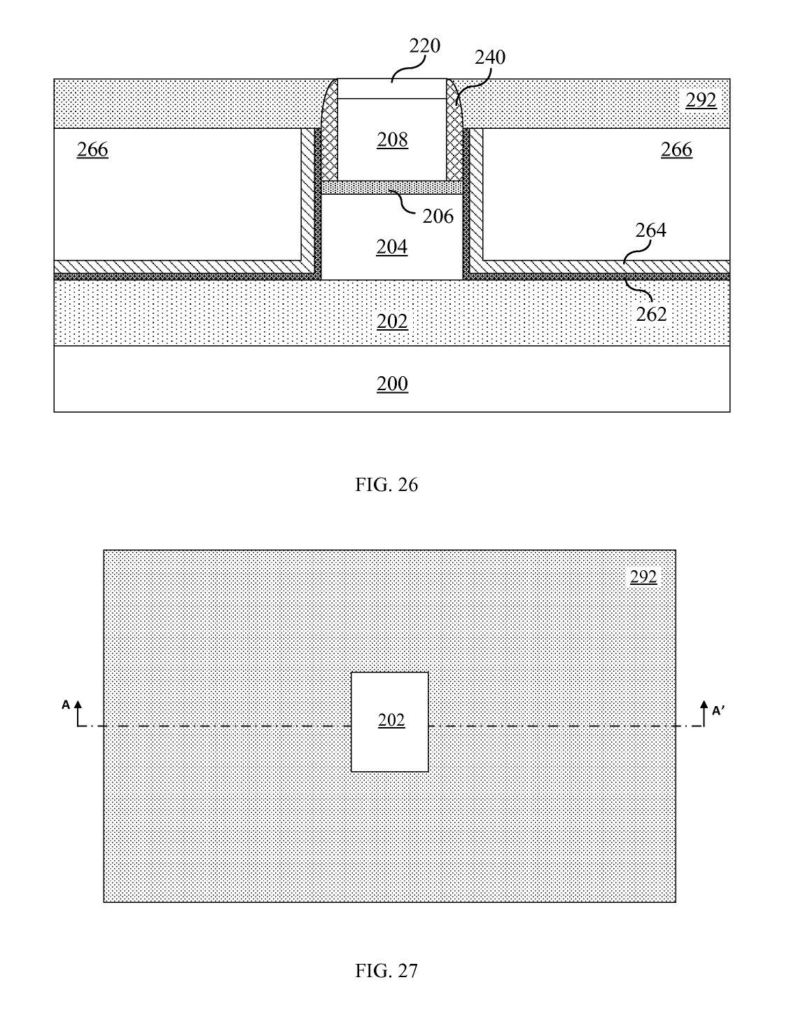

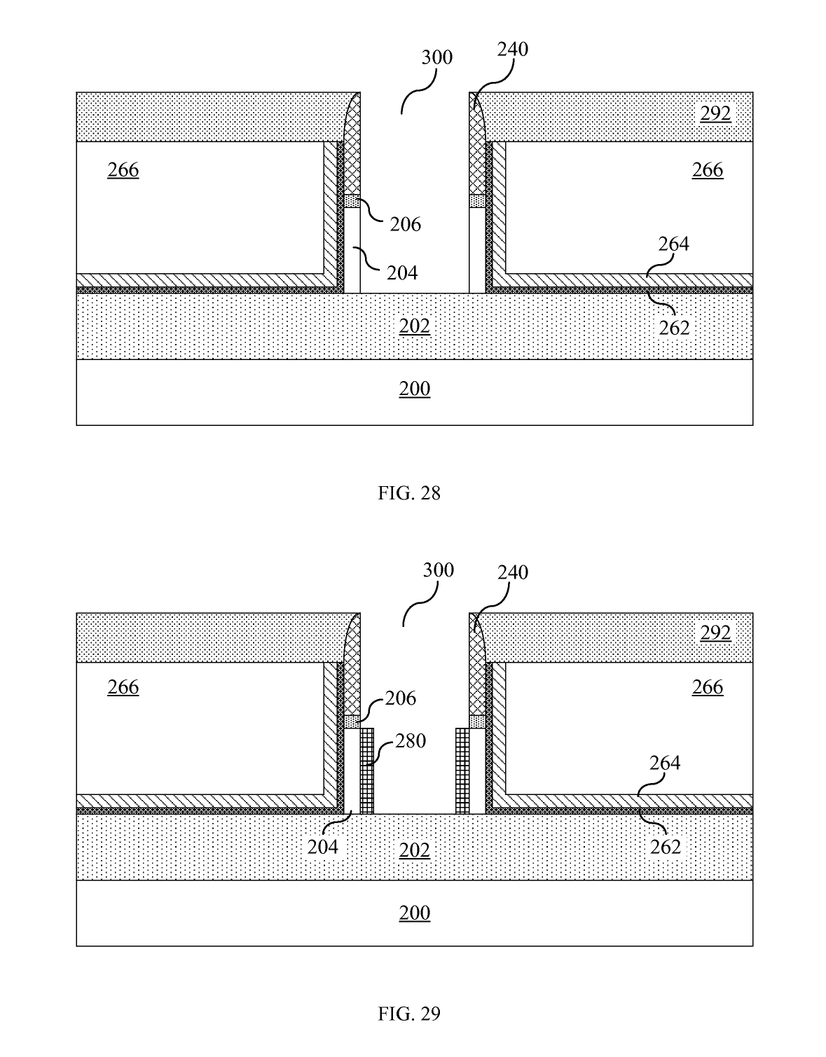

Then, a cavity 300 is formed. Firstly, as shown in FIG. 21 and FIG. 22, a first dielectric layer 290 (e.g. SiO₂) is deposited and planarized so as to expose the second auxiliary mask layer 284 in the auxiliary mask layer. Then, as shown in FIG. 23 and FIG. 24, the second auxiliary mask layer 284 (Si₃N₄), the first auxiliary mask layer 282 (SiO₂) and a portion with certain height of the gate stack structure are removed to form gates 266. In the direction of the thickness of the Si layer 204, the gates 266 are at least higher than the Si layer 204 (for the purpose of forming the channel), thus it is favorable for increasing the effective area of the channel region in the device, so as to further improve the carrier mobility in the channel region. The protective layer 220 of certain thickness still remains after the operation. As further shown in FIG. 25 and FIG. 26, a second dielectric layer 292 is formed (e.g. SiO₂ for reducing damage to the formed structure when the protective layer 220 is removed to form the cavity). The second dielectric layer 292 exposes the protective layer 220 but covers the first sidewall spacers 240 and the second sidewall spacers 242. Aforesaid operation may be implemented by way of firstly depositing the second dielectric layer 292 and then performing CMP to the second dielectric layer 292. Referring to FIG. 27 and FIG. 28, the protective layer 220, the sacrificial layer 208, the stop layer 206 and the Si layer 204 are removed with the second dielectric layer 292 as a mask, so as to expose the insulating layer 202 and form the cavity 300. Although it appears that other structures are not greatly affected at the formation of the cavity 300 owing to protection from the second dielectric layer 292, the shape of the cavity 300 is determined due to the existence of the first sidewall spacers 240 and the second sidewall spacers 242. Therefore, to an certain extent, the first sidewall spacers 240 and the second sidewall spacers 242 also function as masks, which in turn decreases the number of mask plates and is favorable for simplifying the processes. Since the cavity 300 is formed after the formation of the source and drain regions, the source and drain regions are no longer affected by the reaction force provided by the Si layer 204 (the first semiconductor layer), the stop layer 206 and the sacrificial layer 208 that are formerly filled in the cavity 300, such that the loss of the stress of the source and drain regions becomes less.

Referring to FIG. 29, after the cavity 300 has been formed, an epitaxial layer 280 is grown on the surface of Si layer 204 on the interior walls of the cavity by means of selective epitaxy. In one example, the epitaxial layer is SiC for an NMOS device. In another example the epitaxial layer is SiGe for a PMOS device. It is favorable for producing stress at the channel region, thereby improving carrier mobility and enhancing performance of the semiconductor devices. The specific processing parameters of the selective epitaxy growth, for example, the processing temperature, reaction period and dopants, may be adjusted according to design of the products, and are not described here in detail in order not to obscure the essence of the invention. FIG. 29 shows the epitaxial layers 280 formed on the Si layers 204 on two sides of the interior walls of the cavity, but it is also applicable to form the epitaxial layer 280 on the Si layer 204 on either side thereof. For instance, it is possible to cover the Si layer 204 on one side with a protective film (not shown), and then the epitaxial layer 280 may be grown on the Si layer 204 on the other side that is not covered.

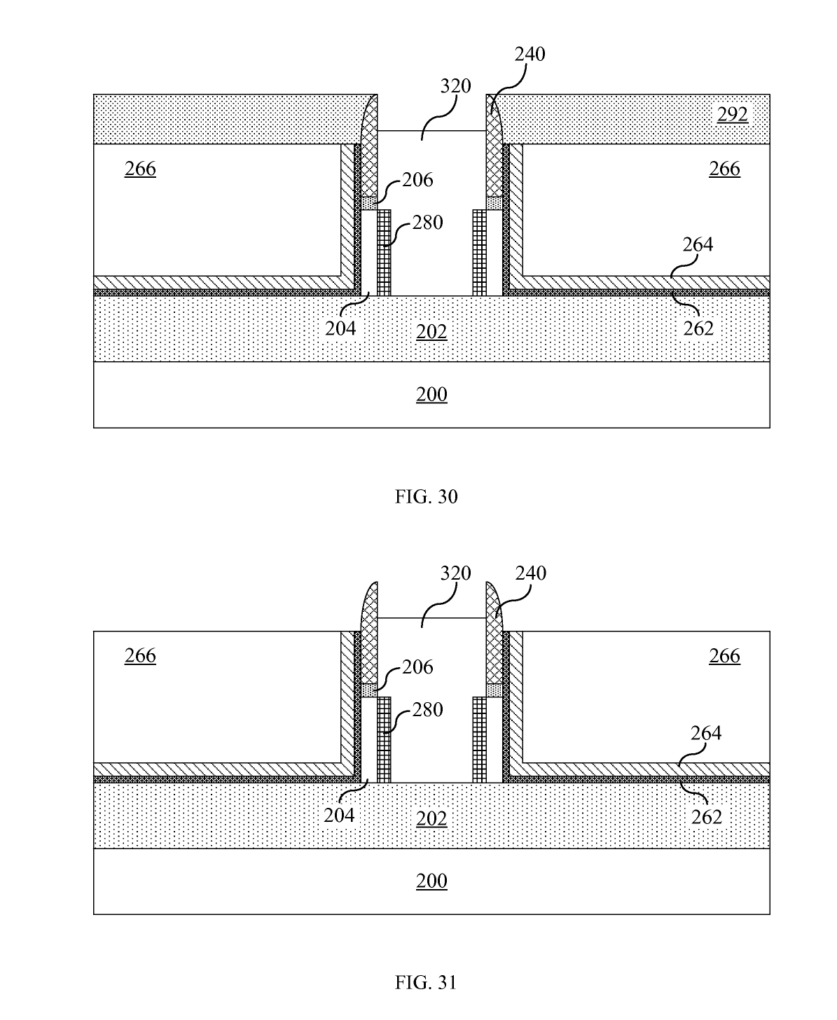

As shown in FIG. 30, an insulating material is filled into the cavity 300, and then the insulating material is etched back to form an insulating plug 320. The material for the insulating plug 320 may be any one or combinations of Si₃N₄, SiO₂ and Si₂N₂O. As the stress of the insulating plug 320 may be adjusted so that, for example, PMOS devices have tensile stress and NMOS devices have compressive stress. The insulating plug may apply stress to the semiconductor base so that an opposite stress may be generated in the semiconductor base, that is, a compressive stress is generated in the semiconductor base of the PMOS device, and a tensile stress is generated in the semiconductor base of the NMOS device. The generated opposite stress is favorable for further regulating the stress at the channel region, thereby further improving the carrier mobility within the channel region. The insulating plug 320 is at least higher than the patterned first semiconductor layer, which in turn helps to uniformly provide stress to the channel region. Then the semiconductor structure is formed.

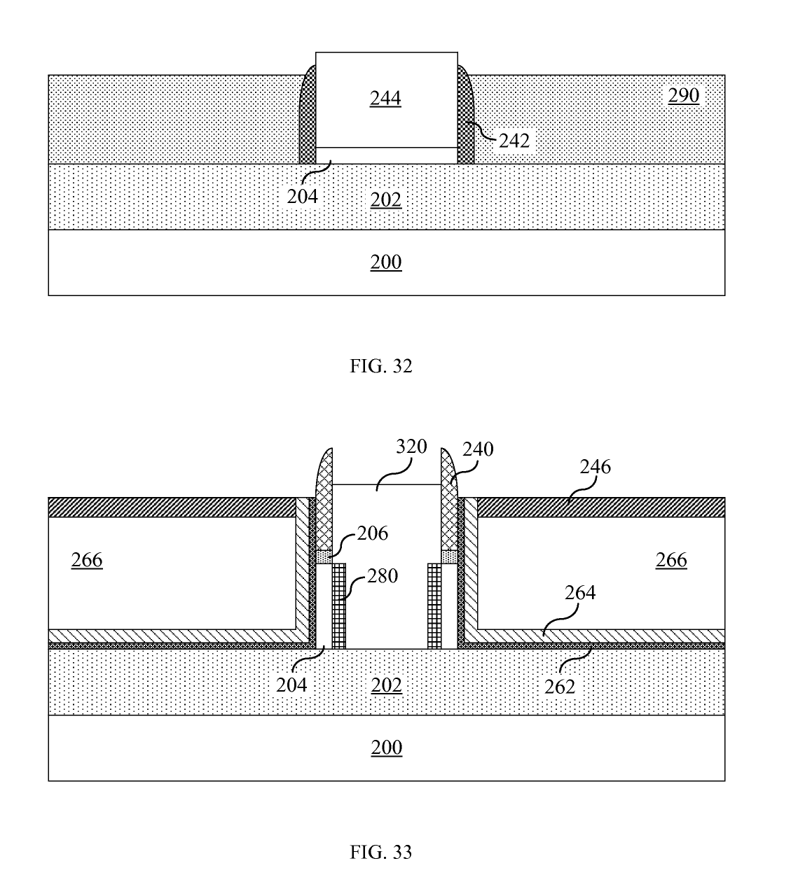

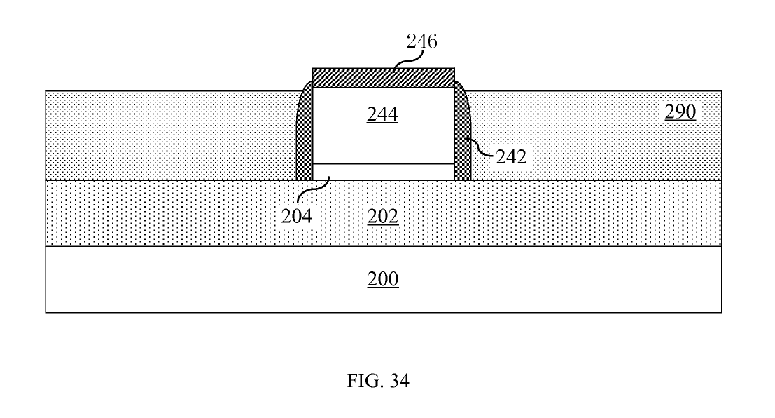

As shown in FIG. 31 and FIG. 32, the second dielectric layer 292 is removed to expose the gates 266 and the source/drain regions 244. As further shown in FIG. 33 and FIG. 34, metal silicide layers 246 (i.e. the contact region for reducing the contact resistance at the time of forming metal interconnect later) may be formed on the gates 266 and the source/drain regions 244 by way of forming metal layers on the gate 266 and the source/drain regions 244 and performing thermal operation thereto, and then further removing the metal layer remains from the reaction.

Although the exemplary embodiments and their advantages have been described herein in detail, it should be understood that various alternations, substitutions and modifications may be made to the embodiments without departing from the spirit of the present invention and the scope as defined by the appended claims. As for other examples, it may be easily appreciated by a person of ordinary skill in the art that the order of the process steps may be changed without departing from the scope of the present invention.

In addition, the scope, to which the present invention is applied, is not limited to the process, mechanism, manufacture, material composition, means, methods and steps described in the specific embodiments in the specification. According to the disclosure of the present invention, a person of ordinary skill in the art should readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A semiconductor structure, comprising:
a semiconductor base on top of an insulating layer which is located on a semiconductor substrate;
source and drain regions adjacent to opposite first sides of the semiconductor base;
gates located on opposite second sides of the semiconductor base;
an insulating plug located on the insulating layer and embedded into the semiconductor base; and
an epitaxial layer between the insulating plug and the semiconductor base, wherein for an NMOS device, the epitaxial layer is SiC, and for a PMOS device, the epitaxial layer is SiGe.

2. The semiconductor structure of claim 1, further comprising:
a channel layer located between the second sides and the epitaxial layer, and/or
the channel layer is located between the second sides and the insulating plug.

3. The semiconductor structure of claim 1, wherein a mask layer is located between the second sides and the insulating plug, and in a direction perpendicular to the semiconductor substrate, the channel layer is located between the insulating layer and the mask layer.

4. A semiconductor structure of claim 1, wherein the thickness of the epitaxial layer is between 5 nm-40 nm in the direction perpendicular to the second sides

5. The semiconductor structure of claim 1, wherein the gates and/or the insulating plug are positioned at least higher than the channel layer in the direction perpendicular to the semiconductor substrate.

6. The semiconductor structure of claim 1, wherein the insulating plug comprises a material selected from a group consisting of Si₃N₄, SiO₂ and Si₂N₂O, or combinations thereof.

7. The semiconductor structure of claim 1, wherein the insulating plug has compressive stress for NMOS devices, and has tensile stress for PMOS devices.

8. The semiconductor structure of claim 1, wherein the first sides are perpendicular to the second sides.

9. The semiconductor structure of claim 1, wherein the percentage of Ge atoms is in the range of about 10%-70% in the SiGe, and the percentage of C atoms is in the range of about 0.2%-2% in the SiC.

10. A method for manufacturing a semiconductor structure, comprising:
forming an insulating layer on a semiconductor substrate;
forming a semiconductor base on the insulating layer;
forming gates located on opposite first sides of the semiconductor substrate;
forming source and drain regions adjacent to opposite second sides of the semiconductor substrate;
removing a part of the semiconductor base therein to form a cavity in the semiconductor base, wherein the cavity exposes the insulating layer;
forming an epitaxial layer by means of selective epitaxy of SiGe or SiC within the cavity; and
forming an insulating plug in the cavity.

11. The method of claim 10, wherein the step of forming a semiconductor base comprises:
forming a first semiconductor layer, a stop layer, a patterned sacrificial layer and protective layer on the insulating layer, and forming first sidewall spacers to surround the patterned sacrificial layer and the protective layer;
forming a patterned stop layer and the first semiconductor layer with the first sidewall spacers as masks;
forming source/drain regions and removing the first sidewall spacers, the protective layer and the sacrificial layer that cover the source/drain regions, so as to expose the stop layer; and
forming second sidewall spacers surrounding the protective layer and the sacrificial layer, and wherein the step of forming a cavity in the semiconductor base comprises:
removing the protective layer, the sacrificial layer and the first semiconductor layer with the first sidewall spacers and the second sidewall spacers as masks, and wherein the material of the stop layer is different from the protective layer, the sacrificial layer, the first semiconductor layer, the first sidewall spacers, and the second sidewall spacers.

12. The method of claim 10, wherein the insulating plug is positioned at least higher than the patterned first semiconductor layer in the direction perpendicular to the semiconductor substrate.

13. The method of claim 10, wherein the epitaxial layer is formed at least on one interior wall of the cavity in the direction perpendicular to the second sides, and the epitaxial layer at least covers the patterned first semiconductor layer.

14. The method of claim 10, wherein the thickness of the epitaxial layer is between 5 nm-40 nm in the direction perpendicular to the second sides.

15. The method of claim 10, wherein the first sides are perpendicular to the second sides.

16. The method of claim 10, wherein the insulating plug comprises a material selected from a group consisting of Si₃N₄, SiO₂ and Si₂N₂O or combinations thereof.

17. The method of claim 10, wherein the epitaxial layer is SiC for an NMOS device and the percentage of C atom is in the range of about 0.2%-2%, and the epitaxial layer is SiGe for a PMOS device and the percentage of Ge atom is in the range of about 10%-70%.

18. The semiconductor structure of claim 2, wherein the gates and/or the insulating plug are positioned at least higher than the channel layer in the direction perpendicular to the semiconductor substrate.

19. The semiconductor structure of claim 2, wherein the insulating plug comprises a material selected from a group consisting of Si₃N₄, SiO₂ and Si₂N₂O, or combinations thereof.

20. The semiconductor structure of claim 2, wherein the insulating plug has compressive stress for NMOS devices, and has tensile stress for PMOS devices.
